(19) United States
(12) Patent Application Publication
(10) Pub. No.: US 2019/0114755 A1
(43) Pub. Date: Apr. 18, 2019

(54) SEMICONDUCTOR CHIP INSPECTION DEVICE

(71) Applicant: Samsung Electronics Co., Ltd., Suwon-si (KR)

(72) Inventors: Seong Sil LEE, Hwaseong-si (KR); Sung Yoon RYU, Suwon-si (KR); Young Hoon SOHN, Incheon (KR); Chung Sam JUN, Suwon-si (KR)

(21) Appl. No.: 15/937,551

(22) Filed: Mar. 27, 2018

(30) Foreign Application Priority Data
Oct. 13, 2017 (KR) 10-2017-0133184

(51) Int. Cl. G06T 7/00; G01J 5/02; G01N 25/72; H04N 5/33

(52) U.S. Cl. CPC G06T 7/001; G01J 5/0255; G01J 2005/0077; H04N 5/33; G01N 25/72

(57) ABSTRACT

According to one embodiment, a semiconductor chip inspection device includes a conveyor, an image capture device, and an analysis system. The conveyor provides a transfer path on which a semiconductor chip heated during a manufacturing process is moved. The image capture device is disposed above the transfer path and is configured to generate a thermographic image by imaging the semiconductor chip including capturing a plurality of thermographic images at different focal points in a thickness direction of the semiconductor chip. The analysis system is configured to compare the plurality of thermographic images with a plurality of standard images provided in advance, and to detect a region in which a temperature differential between a thermographic image and a respective standard image exceeds a reference value.

### CROSS-REFERENCE TO RELATED APPLICATION

This application claims the benefit of priority to Korean Patent Application No. 10-2017-0133184 filed on Oct. 13, 2017, with the Korean Intellectual Property Office, the disclosure of which is incorporated herein by reference in its entirety.

### BACKGROUND

### 1. Field

The present disclosure relates to a semiconductor chip inspection device.

### 2. Description of Related Art

In a process of manufacturing semiconductor chips, a plurality of processes are sequentially performed. Thus, in a case in which defects occur in any one process, defects may be present until a final process. Thus, in order to improve productivity, a process of detecting and removing a defective semiconductor chip before a manufacturing process is completed is significant. In the case of optical inspection equipment or electron-beam (e-beam) inspection equipment, defects visible on the surface of semiconductor chips may be easily detected, but there are limitations in detecting defects occurring inside of semiconductor chips. Since an inspection to confirm whether semiconductor chips are able to operate normally by supplying power to semiconductor chips is possible after semiconductor chips have been manufactured, there have been limitations in removing defective semiconductor chips in an early stage.

### SUMMARY

An aspect of the present inventive concept is to provide a semiconductor chip inspection device detecting a defect in a semiconductor chip in an early stage.

According to one embodiment, a semiconductor chip inspection device includes a conveyor, an image capture device, and an analysis system. The conveyor provides a transfer path on which a semiconductor chip heated during a manufacturing process is moved. The image capture device is disposed above the transfer path and is configured to generate a thermographic image by imaging the semiconductor chip including capturing a plurality of thermographic images at different focal points in a thickness direction of the semiconductor chip. The analysis system is configured to compare the plurality of thermographic images with a plurality of standard images provided in advance, and to detect a region in which a temperature differential between a thermographic image and a respective standard image exceeds a reference value.

According to one embodiment, a semiconductor chip inspection device includes a chamber, a conveyor, an image capture device, and an analysis system. The conveyor is accommodated in the chamber and provides a transfer path on which a semiconductor chip, heated to a temperature higher than a temperature in the chamber, is moved. The image capture device is disposed above the transfer path and is configured to generate a thermographic image by imaging the semiconductor chip, including capturing a plurality of thermographic images at different focal points in a thickness direction of the semiconductor chip. The analysis system is configured to generate a thermographic image group by processing the plurality of thermographic images and detecting a region in which a temperature differential between the thermographic image group and a standard image group, provided in advance, exceeds a reference value, to detect a defect in the semiconductor chip.

According to one embodiment, a semiconductor chip inspection device includes a transfer portion, a shooting portion, and an analysis portion. The transfer portion provides a transfer path on which a semiconductor chip cooled from a first temperature to a second temperature during a transfer process is moved. The shooting portion is disposed above the transfer path and is configured to capture a thermographic image of the semiconductor chip. The analysis portion is configured to detect a region in which a temperature differential exceeds a reference value by comparing the thermographic image with a plurality of standard images provided in advance, while detecting a section having a highest temperature and a section having a lowest temperature in the thermographic image and multiplying values of the thermographic image by an amplifier factor allowing a temperature differential in the section having a highest temperature and the section having a lowest temperature to be increased.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic diagram of a semiconductor chip inspection device according to an example embodiment;

FIG. 2 is an enlarged view of portion ‘A’ of FIG. 1;

FIG. 3 is a view of a semiconductor chip being imaged at different focal points by a shooting portion, according to an example embodiment;

FIG. 4 includes parts (a), (b), and (c), which are schematic views of a thermographic image group generated in an analysis portion;

of FIG. 5 includes parts (a), (b), and (c), which are schematic views of a standard image group;

FIG. 6 includes parts (a), (b), and (c), which are schematic views of a result of subtraction process of a thermographic image group and a standard image group;

FIG. 7 is a modified example of a semiconductor chip inspection device of FIG. 1, according to an example embodiment; and

FIG. 8 is a flowchart illustrating main operations of a method of inspecting a semiconductor device using a semiconductor chip inspection device of FIG. 1, according to an example embodiment.

### DETAILED DESCRIPTION

Hereinafter, example embodiments will be described with reference to the accompanying drawings.

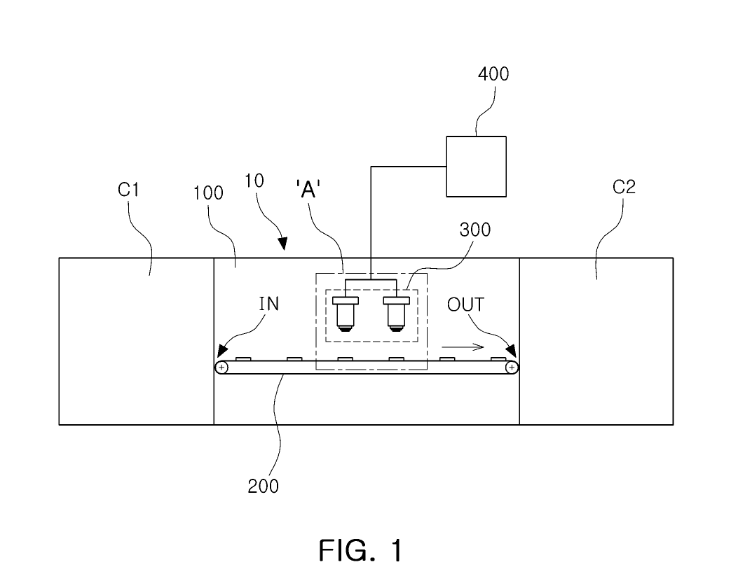

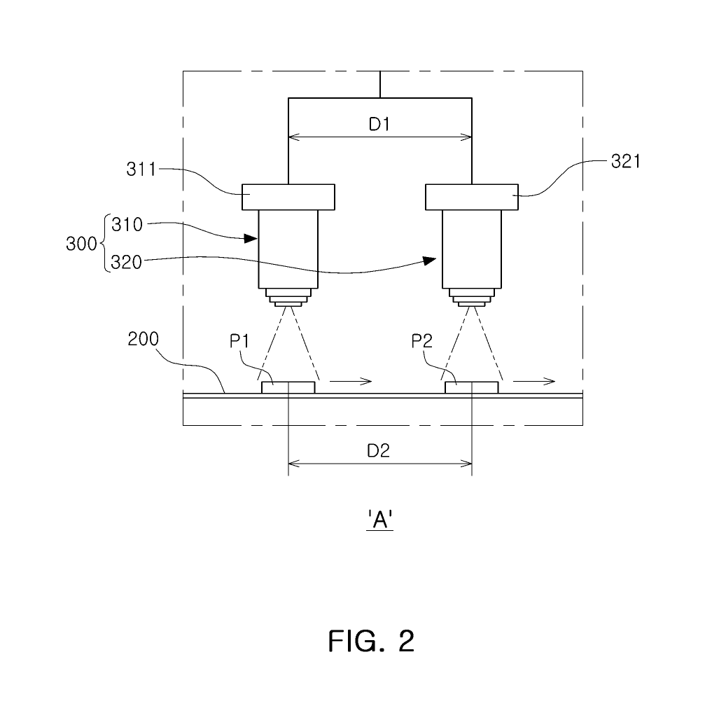

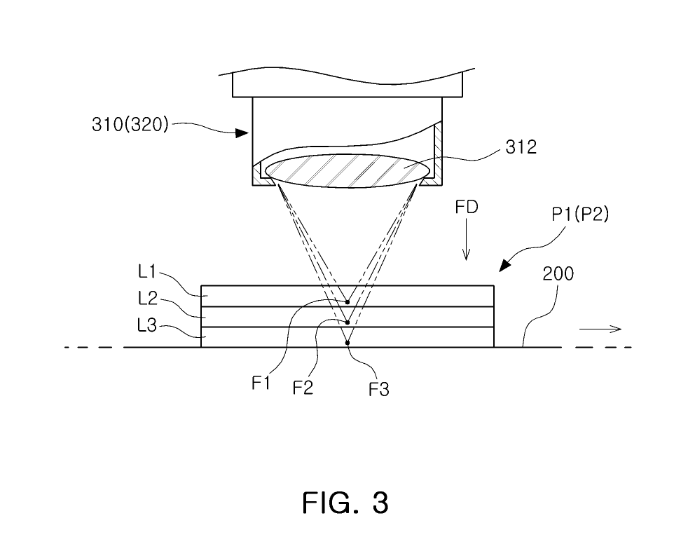

With reference to FIGS. 1 to 3, a semiconductor chip inspection device according to an example embodiment will be described. FIG. 1 is a schematic diagram of a semiconductor chip inspection device according to an example embodiment; FIG. 2 is an enlarged view of portion ‘A’ of FIG. 1; and FIG. 3 is a view of a semiconductor chip being imaged at different focal points by a shooting portion according to an example embodiment.

As used here, a semiconductor chip refers to a die formed from a semiconductor wafer and including an integrated circuit thereon. A semiconductor chip can be a memory chip or a logic chip, for example. A semiconductor chip may be more generally referred to as a semiconductor device, which term is also used to describe a semiconductor package. A semiconductor package may include one or more semiconductor chips stacked on a package substrate, and covered by a molding layer. A semiconductor package may also refer to a package-on-package device including a plurality of packages formed in a stack.

With reference to FIGS. 1 and 2, a semiconductor chip inspection device 10 according to an example embodiment may include a transfer portion 200 transferring semiconductor chips P1 and P2, a shooting portion 300 capturing a thermographic image of the semiconductor chips P1 and P2, and an analysis portion 400 processing and analyzing the thermographic image having been captured. According to an example embodiment, a chamber 100 accommodating the transfer portion 200 may be provided.

The semiconductor chip inspection device 10 may be disposed on a transfer path between processes of manufacturing the semiconductor chip. In addition, in some embodiments, the semiconductor chip inspection device 10 may be disposed between a process of heating the semiconductor chip and a subsequent process thereof in a manufacturing process. For example, the semiconductor chip inspection device 10 may be disposed between a molding process in which the semiconductor chip is heated while a molding material is placed to cover the semiconductor chip, and a subsequent process thereof (e.g., sorting, marking, or testing) during a process of packaging the semiconductor chip. In this manner, inspection of the semiconductor chip by the semiconductor chip inspection device 10 may occur after the semiconductor chip is in package form, including an encapsulating molding layer.

The semiconductor chips P1 and P2 loaded into the semiconductor chip inspection device 10 of an example embodiment may be provided in a state of being heated to a first temperature in the previous process. The semiconductor chips P1 and P2 heated may be gradually cooled to a second temperature in a process of being transferred in the semiconductor chip inspection device 10. According to an example embodiment, a temperature measuring device measuring a temperature of the semiconductor chip may be disposed in an inlet portion IN and an outlet portion OUT of the semiconductor chips P1 and P2 of the semiconductor chip inspection device 10. For example, the temperature measuring device may include one or more temperature sensors connected to a processor. The processor maybe part of the analysis portion 400, or may be separate from the analysis portion 400. In a case in which a decrease in a temperature measured in the inlet portion IN and the outlet portion OUT exceeds a reference value, a temperature maintaining system reducing a speed at which the semiconductor chips P1 and P2 are cooled may be included therein.

The previous process is provided as a process of inevitably heating the semiconductor chip in a process of manufacturing the semiconductor chip and refers to a process in which the semiconductor chip is heated in a process of forming an encapsulation layer on an exterior of the semiconductor chip using the molding material in a manner similar to the molding process cited as an example. In detail, when the semiconductor chip is heated in the molding process, the first temperature may be within a range of 130° C. to 150° C., while the second temperature may be room temperature. Thus, in the case of an example embodiment, since a separate heating device for heating the semiconductor chip before being loaded into the semiconductor chip inspection device 10 is unnecessary, a delay of the manufacturing process caused by further heating the semiconductor chip to be inspected may be prevented. The semiconductor chips P1 and P2 of an example embodiment may be provided as a packaged semiconductor chip, but are not limited thereto. For example, the semiconductor chips P1 and P2 may be provided as a semiconductor chip in a state before being packaged, or in a wafer state, and in certain embodiments, inspection may occur after a natural heating process during the processing of the semiconductor chip or wafer.

The chamber 100 may be disposed on a moving path connecting a chamber C1 of the previous process to a chamber C2 of a subsequent process. The chamber 100 may be provided to have a size sufficient to accommodate the transfer portion 200 in an internal space thereof. According to an example embodiment, the chamber 100 may be provided to have a size sufficient to accommodate the shooting portion 300 therein. An observation window may also be disposed on a side wall thereof, in order to observe an interior of the chamber 100 from an exterior thereof.

An internal temperature of the chamber 100 may be lower than a first temperature, such as a temperature of the semiconductor chips P1 and P2 entered through the inlet portion IN. Thus, the semiconductor chips P1 and P2 may be cooled while being moved in the interior of the chamber 100. The chamber 100 may be an enclosed space, having four walls, a top ceiling, and a bottom floor, and may have one or more doors or entryways through which the semiconductor chips P1 and P2 may enter and exit.

The transfer portion 200, which may be a conveyor, may connect the chamber C1 of the previous process to the chamber C2 of the subsequent process and may employ various transfer means continuously transferring the semiconductor chip along a predetermined path. In an example embodiment, a conveyor belt may be employed.

The shooting portion 300 may be disposed above a transfer path of the semiconductor chips P1 and P2 and may capture a thermographic image of the semiconductor chips P1 and P2 to be transmitted to the analysis portion 400.

As illustrated in FIG. 2, the shooting portion 300, also described as an image capture device, may be disposed above the transfer portion 200 and include one or more thermographic cameras 310 and 320 arranged along the transfer portion 200. In a case in which the transfer portion 200 includes a plurality of thermographic cameras 310 and 320, the plurality of thermographic cameras 310 and 320 may be disposed to be spaced apart from each other in such a manner that a distance D1 between central portions thereof is equal to a distance D2 between central portions of the semiconductor chips P1 and P2. The thermographic cameras 310 and 320 may detect heat emitted from the semiconductor chip and may output a thermographic image representing a temperature distribution of heat, having been emitted, using color to represent different temperatures, for example. Other representations of temperature may be used, such as grayscale or other single-color scale, where amount/intensity of darkness or lightness of the image represents higher and lower temperatures. In this manner, the shooting portion 300 is configured to generate a thermographic image by imaging each semiconductor chip. In general, a process of manufacturing the semiconductor chip may include a plurality of processes sequentially performed, while the semiconductor chip may have a defect occurring in respective processes. In detail, the defect may frequently occur in the molding process in which the semiconductor chip is heated. In the molding process, a catalyst, such as phosphorous (P), may be concentrated on an end portion of the semiconductor chip. In this case, when moisture is in contact with the end portion, a defect in which the molding material is peeled off may occur. However, a defect occurring in a process of molding the semiconductor chip may be present inside the molding. Thus, there is a limitation for confirming that a defect has occurred in the semiconductor chip using optical inspection equipment or electron-beam (e-beam) inspection equipment of the related art, because such equipment is only able to confirm a defect visible on a surface of the semiconductor device that includes the semiconductor chip, and so after the molding process, the surface of the semiconductor chip is no longer visible.

In an example embodiment, a thermographic image of the semiconductor chip may be imaged to be compared with the thermographic image of the semiconductor chip normally operated (e.g., having no defects), thereby confirming whether the semiconductor chip has a defect or not. A defect occurring in a process of manufacturing the semiconductor chip may occur, for example, when a lithography process or an etching process is not performed as desired, when a foreign substance is introduced from an external source during a manufacturing process, when a chemical change, such as oxidation, occurs in a structure formed using a semiconductor layer, or when a crack occurs therein. Due to a difference in physical properties of defect, a region in which the defect has occurred has a difference in thermal conductivity from the same region of a normal, non-defective semiconductor chip. Thus, heat emitted from the region in which the defect has occurred has a distribution different from that of heat emitted from the same region of a normal, non-defective semiconductor chip. Since infrared light wavelengths generated by heat described above have a higher level of transmittance than that of light having other wavelengths, infrared light wavelengths emitted from a lower portion of the semiconductor chip may be easily detected.

In an example embodiment, a thermal distribution of the semiconductor chip may be confirmed through a thermographic image to be compared with a thermal distribution of a normal (e.g., non-defective) semiconductor chip, thereby confirming whether a defect has occurred in the semiconductor chip being measured.

According to an example embodiment, the thermographic cameras 310 and 320 may be connected to moving stages 311 and 321, respectively. Thus, according to need, a plurality of thermographic images may be captured in such a manner that the thermographic cameras 310 and 320 are moved to the left or right, or a focal point is changed in a thickness direction of an object by moving the thermographic images up and down.

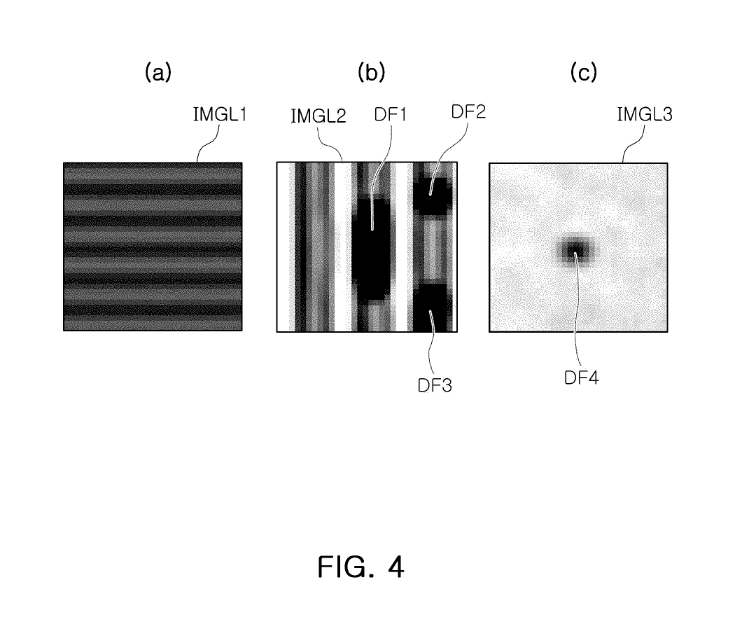

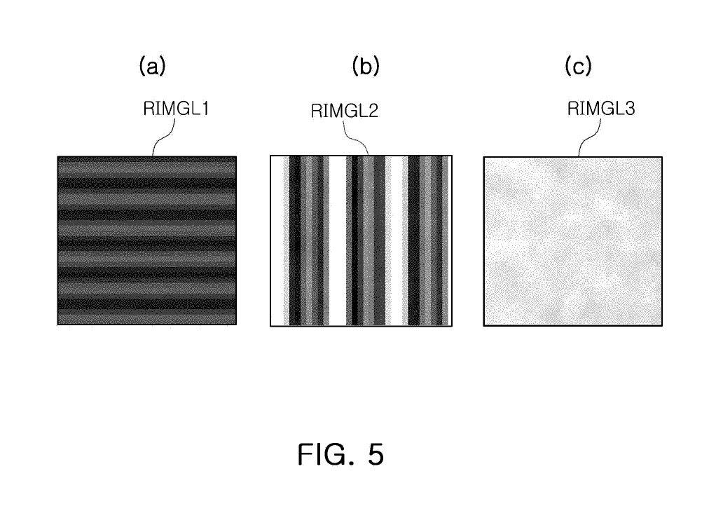

FIG. 3 illustrates a process in which a thermographic camera 310 captures three pieces of thermographic images at different focal points F1, F2, and F3, in a thickness direction from a front surface FD of a semiconductor chip P1. (a) to (c) of FIG. 4 illustrate three pieces of thermographic images IMGL1 to IMGL3, having been captured.

The thermographic camera 310 may capture thermographic images of virtual layers L1, L2, and L3, stacked in the thickness direction at different focal points F1, F2, and F3. Each virtual layer corresponds to a constant vertical height within the semiconductor chip and the items and components of the chip that exist at that vertical height. The thermographic camera 310 may sequentially capture a thermographic image in a direction from a layer L1 corresponding to a surface of a semiconductor chip P1 to a layer L3 disposed in a lowermost portion of the semiconductor chip P1 at different focal points of a lens 312. According to an example embodiment, the thermographic image may be captured by sequentially increasing a focal length in the thickness direction of the semiconductor chip P1 before the thermographic image of a transfer portion 200 is captured. Thus, a plurality of thermographic images according to thicknesses of various types of semiconductor chips having different thicknesses may also be captured.

According to an example embodiment, a thermographic camera may be disposed in an inlet portion IN and an outlet portion OUT of a semiconductor chip inspection device 10, and an average value of a thermographic image captured by the thermographic camera may be calculated, thereby measuring temperatures of the components or regions of semiconductor chips P1 and P2 as an average. For example, a first image at a first temperature may show certain first temperature distributions, and a second image at a second temperature may show certain second temperature distributions. The temperature distributions may show up as different intensities of detected heat. Thus, the two images may be averaged to result in an averaged image for each of the semiconductor chips. Thus, the shooting portion 300 may include first cameras (e.g., one or more cameras to shoot one or more respective semiconductor chips) for shooting the semiconductor chips near the inlet portion IN of the semiconductor chip inspection device 10, and may include second cameras (e.g., one or more cameras to shoot one or more respective semiconductor chips) for shooting the semiconductor chips near the outlet portion OUT of the semiconductor chip inspection device 10

An analysis portion 400 may compare a thermographic image captured by a shooting portion 300 with a plurality of standard images provided in advance to detect a region in which a temperature differential (e.g., between the captured thermographic image and one of the standard images) exceeds a reference value, thereby detecting a defect in the semiconductor chips P1 and P2. The analysis portion 400, also described as an analysis system, may be implemented by a computer and may include known computer technology, such as processing and memory hardware, input/output interfaces, and various software programs that configure the analysis system to perform this detection by performing various calculations and comparisons such as described herein. Also, it should be noted that as is traditional in the field of the disclosed technology, features and embodiments are described, and illustrated in the drawings, in terms of devices or systems relating to processing technology, such as computers. Those skilled in the art will appreciate that these devices and systems are physically implemented by electronic (or optical) circuits such as logic circuits, discrete components, microprocessors, hard-wired circuits, memory elements, wiring connections, and the like, and they may be programmed using software (e.g., microcode) to perform various functions discussed herein and may optionally be driven by firmware. Also, devices or systems of the embodiments may be a single device (e.g., standalone computer) or may be physically separated into two or more interacting and discrete units without departing from the scope of the inventive concepts.

Descriptions of this detection process will be provided in detail. For example, in one embodiment, the analysis portion 400 may store a plurality of thermographic images of each of the semiconductor chips P1 and P2 captured in the shooting portion 300, to be processed, thereby generating a thermographic image group corresponding to each of the semiconductor chips P1 and P2. In this case, the analysis portion 400 may perform signal processing to amplify a defective signal, in order to emphasize the defective signal included in the thermographic image. As an example of the signal processing described above, a region having the highest temperature and a region having the lowest temperature in a captured thermographic image may be detected, and an amplifier factor allowing a temperature differential in sections described above to be increased may be multiplied by a value, thereby emphasizing the defective signal compared with other signals.

In addition, the analysis portion 400 may process a plurality of standard images provided in advance, thereby generating a standard image group. The analysis portion 400 may compare the standard image group with respective thermographic image groups and detect a region in which a temperature differential exceeds the reference value, thereby determining whether a defect has occurred in the semiconductor chips P1 and P2. The plurality of standard images may be provided as data previously stored in the analysis portion 400 and may include data storing a thermographic image of a semiconductor chip which may commonly be discriminated.

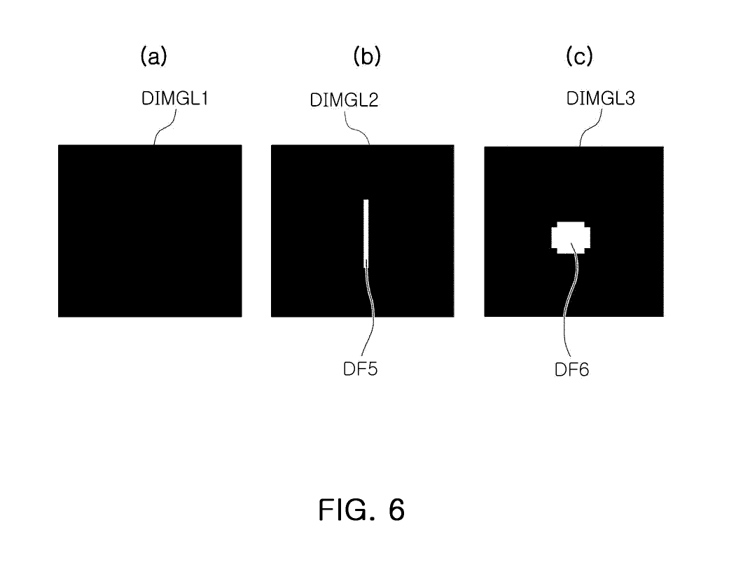

Descriptions thereof will be provided in detail with reference to (a) of FIG. 4 to (c) of FIG. 6.

(a) to (c) of FIG. 4 are schematic views of a thermographic image group generated in an analysis portion; (a) to (c) of FIG. 5 are schematic views of a standard image group corresponding thereto; and (a) to (c) of FIG. 6 are schematic views of a result of subtraction process of the thermographic image group and the standard image group. Reference numerals DF1 to DF4 of (b) of FIG. 4 mark a region in which a defect is imaged.

The analysis portion 400 may process thermographic images IMGL1 to IMGL3 of (a) to (c) of FIG. 4 to generate a single thermographic image group and may perform a subtraction process on standard images RIMGL1, RIMGL2, and RIMGL3 of the standard image group of (a) to (c) of FIG. 5, corresponding thereto, thereby generating result values DIMGL1 to DIMGL3 of (a) to (c) of FIG. 6. In one embodiment, FIG. 4 may represent three different vertical layers within a single semiconductor chip. In some cases, such as depicted in FIG. 4, even in the case in which the thermographic images IMGL1 to IMGL3, having been captured, are not the same as the standard images RIMGL1 to RIMGL3, the thermographic images IMGL1 to IMGL3 and the standard images RIMGL1 to RIMGL3 may be determined to have the same value (and thus be non-defective), when a difference therebetween is lower than a predetermined reference value. For example, in a case in which an imaged defect has a size (e.g., physical size such as an area, or intensity size such as a temperature difference) less than that of the reference value, the thermographic images IMGL1 to IMGL3 and the standard images RIMGL1 to RIMGL3 may be determined to have the same value. It can be confirmed that defects DF2 and DF3 having a relatively small size, among defects DF1 to DF3 imaged in (b) of FIG. 4, are not determined to be defective in a result value of (b) of FIG. 6. In this sense, detected defects, also described as potential defects, may be different from determined defects, based on a threshold value above which detected defects are determined to be defects, but below which detected defects are determined not to be defects. The threshold value may correspond to a size or intensity of a difference between the standard image and the thermographic image.

Since (a) of FIG. 6 does not include the region in which a defect is imaged, a defect region is not marked in a result value DIMGL1. However, it can be confirmed that defects DF5 and DF6 are imaged in (b) and (c) of FIG. 6. Thus, the analysis portion 400 may confirm whether a defect is imaged in a captured thermographic image by confirming the result value. The analysis portion 400 may determine a position in which an actual defect has occurred in a semiconductor chip P1 based on a process described above and mark the position. In addition, the position in which the defect has occurred in the semiconductor device may be stored to establish a database, and data on the region in which the defect has occurred may be provided to a user, and may be used for subsequent design and/or manufacturing processes (e.g., to correct the defect).

According to an example embodiment, a semiconductor chip inspection device 10 may further include a sorting system sorting and removing a semiconductor chip confirmed as having a defect. For example, the sorting system may include a mechanical sorting track or robot arm configured by software to sort and remove a semiconductor chip confirmed as having a defect.

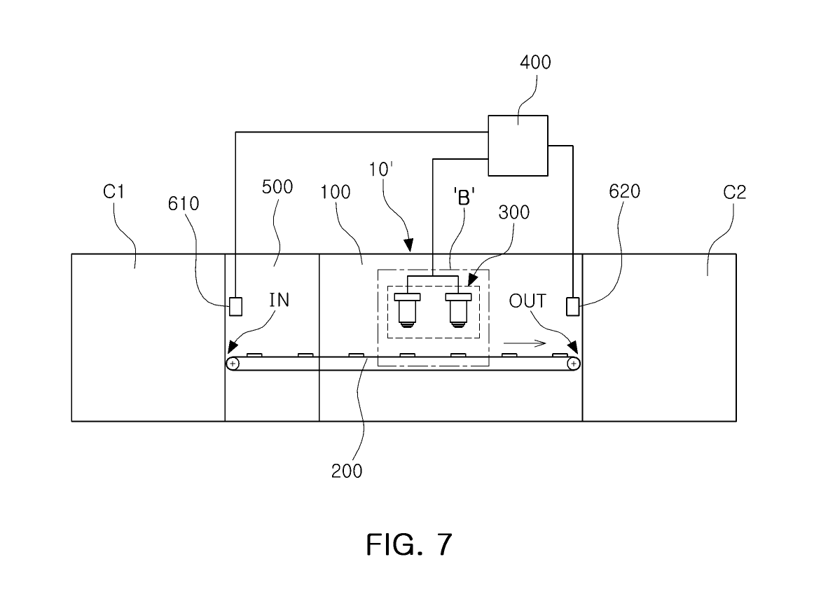

FIG. 7 is a modified example of a semiconductor chip inspection device 10 of FIG. 1. Since portion ‘B’ of FIG. 7 is the same as an example of FIG. 2, descriptions thereof will be provided with reference to FIG. 2. Components corresponding to components described above will be described using the same reference numerals.

The semiconductor chip inspection device 10′ of FIG. 7 is different in that a temperature maintaining system 500 to reduce a speed at which semiconductor chips P1 and P2 are cooled is further included in the semiconductor chip inspection device 10 of FIG. 1. In the semiconductor chip inspection device 10′, a first temperature measuring device 610 (e.g., a sensor) and a second temperature measuring device 620 (e.g., a sensor), measuring temperatures of semiconductor chips P1 and P2, respectively, may be disposed in an inlet portion IN and an outlet portion OUT. The semiconductor chip inspection device 10′ may detect a decrease in temperature of the semiconductor chips P1 and P2, based on a temperature measured in each of the first temperature measuring device 610 and the second temperature measuring device 620. In a case in which the decrease in temperature exceeds a reference value, the temperature of the semiconductor chips P1 and P2, the semiconductor chips P1 and P2 may be heated to a temperature within a range in which the temperatures of the semiconductor chip P1 and P2 do not exceed a temperature measured in the inlet portion IN, thereby reducing the speed at which the semiconductor chips P1 and P2 are cooled. For example, the heating may be controlled by a heating element and a controller that is part of analysis system 400, or that is separate from analysis system 400.

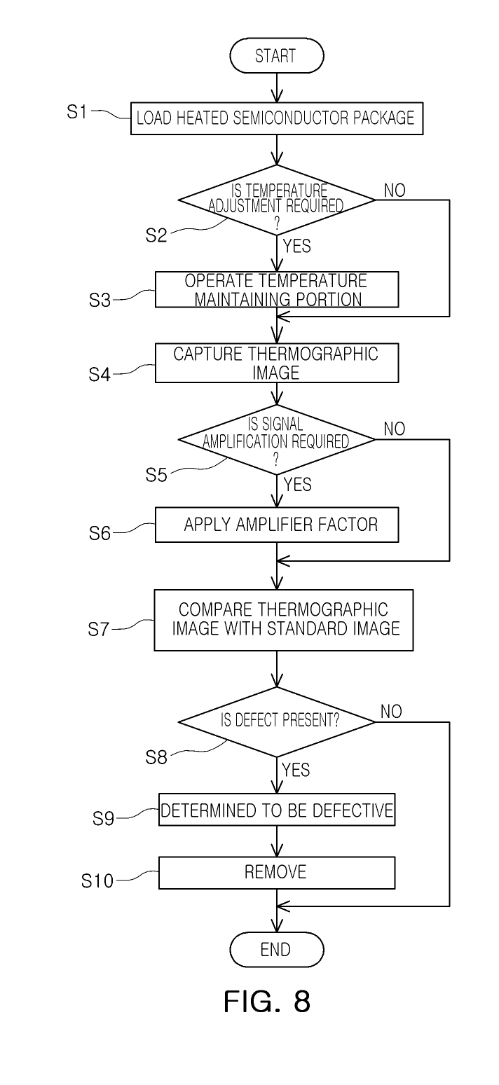

Subsequently, with reference to FIG. 8, a method of inspecting a semiconductor device using a semiconductor chip inspection device according to certain embodiments will be described. Components corresponding to components described above will be described using the same reference numerals.

First, the semiconductor chip heated to a first temperature in the previous process may be loaded into a semiconductor chip inspection device 10 in S1. A semiconductor chip P1 may be continuously transferred along a transfer path on a transfer portion 200 of the semiconductor chip inspection device 10 by a predetermined interval. Descriptions below are a case in which the semiconductor chip P1 is loaded into the transfer portion 200, and a temperature value of the semiconductor chip, having been previously loaded, is stored in the analysis portion 400.

The analysis portion 400 may confirm whether a temperature value of a semiconductor chip stored therein is lower than a reference value and determine whether a temperature of the semiconductor chip P1 transferred along the transfer path may be adjusted, in S2. In a case in which a temperature is required to be adjusted, a temperature maintaining system reducing a decrease in a temperature of the semiconductor chip may be operated in S3.

Subsequently, a shooting portion 300, also described as an image capture device may capture a thermographic image of the semiconductor chip P1 to be transmitted to the analysis portion 400 in S4.

The analysis portion 400 may determine whether signal amplification of the thermographic image, having been transmitted, is required, in S5. If necessary, the analysis portion 400 may detect a section having a highest temperature and a section having a lowest temperature in the thermographic image and may multiply a value of a thermographic image in the section having a highest temperature and the section having a lowest temperature by an amplifier factor allowing a temperature differential to be increased in S6.

The analysis portion 400 may compare a standard image stored in advance with the thermographic image in S7 and may determine whether a defect is imaged in an thermographic image captured by performing a subtraction process in S8. If no defect is present (S7, NO), then the semiconductor chip is transferred to the next manufacturing process. For example, this process could be a marking process or a testing process, or sorting the semiconductor chip into a non-defective chip group.

The analysis portion 400 may confirm the semiconductor chip, corresponding to the thermographic image on which a defect is imaged, is defective in S9 and as a result, the semiconductor chip is selectively removed from the manufacturing process in S10 (e.g., in a sorting process).

As set forth above, according to example embodiments of the present disclosure, a semiconductor chip inspection device may detect a defect in a semiconductor chip in an early stage, thereby improving productivity.

While example embodiments have been shown and described above, it will be apparent to those skilled in the art that modifications and variations could be made without departing from the scope of the present invention as defined by the appended claims.

What is claimed is:

1. A semiconductor chip inspection device, comprising:
a conveyor providing a transfer path on which a semiconductor chip heated during a manufacturing process is moved;
an image capture device disposed above the transfer path and configured to generate a thermographic image by imaging the semiconductor chip including capturing a plurality of thermographic images at different focal points in a thickness direction of the semiconductor chip; and
an analysis system configured to compare the plurality of thermographic images with a plurality of standard images provided in advance, and to detect a region in which a temperature differential between a thermographic image and a respective standard image exceeds a reference value.

2. The semiconductor chip inspection device of claim 1, wherein the analysis system is configured to determine that a defect in the detected region has occurred when the temperature differential exceeds the reference value.

3. The semiconductor chip inspection device of claim 1, wherein the image capture device comprises at least one thermographic camera.

4. The semiconductor chip inspection device of claim 1, wherein the analysis system is configured to generate a thermographic image group by processing the plurality of thermographic images and to analyze the thermographic image by comparing it to a standard image group including the plurality of standard images.

5. The semiconductor chip inspection device of claim 4, wherein the analysis system is configured to compare the thermographic image group with the standard image group, select a thermographic image in which a temperature distribution difference with respect to a respective standard image from the standard image group occurs, and determine a position at which a defect has occurred in the semiconductor chip by using the thermographic image and the temperature distribution difference.

6. The semiconductor chip inspection device of claim 1, wherein the image capture device comprises a plurality of thermographic cameras disposed along the transfer path.

7. The semiconductor chip inspection device of claim 6, wherein the semiconductor chip comprises one of a plurality of semiconductor chips continuously transferred along the transfer path by a predetermined interval, and the plurality of thermographic cameras are disposed to be spaced apart from each other by the predetermined interval.

8. The semiconductor chip inspection device of claim 1, configured such that a temperature of the semiconductor chip decreases while the semiconductor chip is moved along the transfer path.

9. The semiconductor chip inspection device of claim 8, further comprising a temperature measuring device measuring a temperature of the semiconductor chip.

10. The semiconductor chip inspection device of claim 9, further comprising a temperature maintaining system configured to reduce a decrease in the temperature of the semiconductor chip when the decrease in the temperature of the semiconductor chip exceeds a predetermined reference value.

11. The semiconductor chip inspection device of claim 1, wherein the analysis system is configured to detect a section having a highest temperature and a section having a lowest temperature in the thermographic image and to multiply a value of the thermographic image in the section having a highest temperature and the section having a lowest temperature by an amplifier factor allowing a temperature differential to be increased.

12. The semiconductor chip inspection device of claim 1, further comprising a sorting system configured to sort and remove a semiconductor chip that includes a region in which the temperature differential between the thermographic image and the respective standard image exceeds the reference value.

13. A semiconductor chip inspection device, comprising:
a chamber;
a conveyor accommodated in the chamber and providing a transfer path on which a semiconductor chip, heated to a temperature higher than a temperature in the chamber, is moved;
an image capture device disposed above the transfer path and configured to generate a thermographic image by imaging the semiconductor chip, including capturing a plurality of thermographic images at different focal points in a thickness direction of the semiconductor chip; and
an analysis system configured to generate a thermographic image group by processing the plurality of thermographic images and detecting a region in which a temperature differential between the thermographic image group and a standard image group, provided in advance, exceeds a reference value, to detect a defect in the semiconductor chip.

14. The semiconductor chip inspection device of claim 13, wherein the image capture device disposed above the transfer path is configured to image the semiconductor chip a number of times at a time at which the semiconductor chip enters the chamber and at a time at which the semiconductor chip exits the chamber.

15. A semiconductor chip inspection device, comprising:
a transfer portion providing a transfer path on which a semiconductor chip cooled from a first temperature to a second temperature during a transfer process is moved;
a shooting portion disposed above the transfer path and configured to capture a thermographic image of the semiconductor chip; and
an analysis portion configured to detect a region in which a temperature differential exceeds a reference value by comparing the thermographic image with a plurality of standard images provided in advance, while detecting a section having a highest temperature and a section having a lowest temperature in the thermographic image and multiplying values of the thermographic image by an amplifier factor allowing a temperature differential in the section having a highest temperature and the section having a lowest temperature to be increased.

16. The semiconductor chip inspection device of claim 15, further comprising a temperature measuring device configured to measure a temperature of the semiconductor chip.

17. The semiconductor chip inspection device of claim 16, comprising a temperature maintaining system configured to reduce a decrease in the temperature of the semiconductor chip when the decrease in the temperature of the semiconductor chip exceeds a predetermined reference value.

18. The semiconductor chip inspection device of claim 15, wherein the first temperature is within a range of 130° C. to 150° C.

19. The semiconductor chip inspection device of claim 15, further comprising a chamber accommodating the transfer portion,
wherein a temperature in the chamber is lower than the first temperature.

20. The semiconductor chip inspection device of claim 15, wherein the semiconductor chip is gradually cooled from the first temperature to the second temperature during the transfer process.
